(19) United States
(12) Patent Application Publication
(10) Pub. No.: US 2026/0136474 A1
(43) Pub. Date: May 14, 2026

(54) RESIN SEALING APPARATUS, RESIN SEALING METHOD, AND RESIN MOLDING METHOD

(71) Applicant: APIC YAMADA CORPORATION, Nagano (JP)

(72) Inventors: Eiji Nakayama, Nagano (JP); Haruhisa Takahashi, Nagano (JP)

(73) Assignee: APIC YAMADA CORPORATION, Nagano (JP)

(21) Appl. No.: 18/722,605

(22) PCT Filed: Oct. 4, 2022
(86) PCT No.: PCT/JP2022/037052

§ 371 Date: Jun. 21, 2024

(30) Foreign Application Priority Data
Feb. 4, 2022 (JP) 2022-016018

(51) Int. Cl. H05K 3/28

(52) U.S. Cl. CPC H05K 3/284

(57) ABSTRACT

In a resin sealing method, a temperature of a sealing mold for appropriately thermally curing a resin during sealing is taken as a normal setting temperature, and a temperature of the sealing mold higher than the normal setting temperature by a predetermined temperature is taken as a switching setting temperature. In a unit process in which a workpiece and the resin are carried into the sealing mold, sealed, and then carried out as a molded product, with respect to at least one of an upper mold and a lower mold, a setting temperature is changed to increase from the normal setting temperature to the switching setting temperature at a predetermined start timing to control the temperature of the sealing mold, and the setting temperature is changed from the switching setting temperature to the normal setting temperature at a predetermined end timing to control the temperature of the sealing mold.

### TECHNICAL FIELD

The present invention relates to a resin sealing apparatus and a resin sealing method.

### RELATED ART

As examples of a resin sealing apparatus and a resin sealing method that seal a workpiece with an electronic component mounted on a substrate with a sealing resin (hereinafter, simply referred to as a “resin”) and process into a molded product, examples based on a transfer molding method or a compression molding method are known.

The transfer molding method is a technique in which a pot is provided to supply a predetermined amount of resin to two sealing regions (cavities) of upper and lower molds provided at a sealing mold composed of the upper mold and the lower mold, workpieces are arranged respectively at positions corresponding to the sealing regions, and resin sealing is performed by an operation of clamping with the upper mold and the lower mold and flowing the resin from the pot into the cavities (see Patent Document 1: Japanese Patent Application Laid-Open No. 2020-102601). Further, the compression molding method is a technique in which a predetermined amount of resin is supplied to a sealing region (cavity) provided at a sealing mold composed of an upper mold and a lower mold, a workpiece is arranged in the sealing region, and resin sealing is performed by an operation of clamping with the upper mold and the lower mold. As an example, in the case of using a sealing mold with the cavity provided at the upper mold, techniques such as supplying the resin collectively to a center position on the workpiece to perform molding are known. On the other hand, in the case of using a sealing mold with the cavity provided at the lower mold, techniques such as supplying the resin and a film covering a mold surface including the cavity to perform molding are known.

### RELATED ART DOCUMENTS

### Patent Documents

Patent Document 1: Japanese Patent Application Laid-Open No. 2020-102601

### SUMMARY OF INVENTION

### Problems to be Solved by Invention

Herein, in conventional resin sealing apparatuses, generally, the surface temperature of the sealing mold is controlled (adjusted) to be uniform between, for example, 100° C. and 200° C., and the resin used for sealing is managed to be, for example, 30° C. or less. Thus, the following problem is present: in the case of continuing a molding action of performing resin sealing by automatic operation at a constant period, the surface temperature (especially the temperature around a resin accommodating part) of the sealing mold gradually decreases due to the influence of the temperature and the like of the resin accommodated in the sealing mold, the melting point temperature required for resin sealing cannot be secured, and molding defects (insufficient resin curing, non-filling, etc.) occur.

To address such a problem, in the resin sealing apparatus illustrated in Patent Document 1, a technique is disclosed to attempt to prevent a temperature decrease of the sealing mold by adopting an apparatus configuration including temperature sensors respectively at the periphery of a cull block and the cavity, and implementing processes such as temperature information acquisition with no resin accommodated in the sealing mold, temperature information acquisition with the sealing mold unheated, etc. However, there may be problems that the apparatus structure becomes complicated and the costs increase. Furthermore, there may be problems that it takes time and effort to implement the processes of acquiring temperature information in advance, and production efficiency decreases.

### Means for Solving Problems

The present invention has been made in view of the above circumstances, and an objective thereof is to provide a resin sealing apparatus and a resin sealing method capable of preventing gradual decrease in a surface temperature of a sealing mold and occurrence of molding defects by a simple configuration, even in the case of continuing a molding action of performing resin sealing by automatic operation at a constant period.

The present invention solves the above problems by means of solutions described below as an embodiment.

A resin sealing method according to the present invention is a resin sealing method that seals a workpiece with a resin to process into a molded product using a sealing mold including an upper mold and a lower mold. As a requirement, a temperature of the sealing mold set as a temperature for appropriately thermally curing the resin during sealing is taken as a normal setting temperature, and a temperature of the sealing mold set as a temperature higher than the normal setting temperature by a predetermined temperature is taken as a switching setting temperature. In a unit process in which the workpiece and the resin are carried into the sealing mold, sealed, and then carried out as the molded product, with respect to at least one of the upper mold and the lower mold, a setting temperature is changed to increase from the normal setting temperature to the switching setting temperature at a predetermined start timing to control the temperature of the sealing mold, and the setting temperature is changed from the switching setting temperature to the normal setting temperature at a predetermined end timing to control the temperature of the sealing mold.

According to this, it becomes possible to prevent the surface temperature of the sealing mold from gradually decreasing in the case of continuing the molding action by automatic operation at a constant period, without involving a complicated apparatus structure or a complicated implementation process. Thus, when performing resin sealing, since it becomes possible to secure an appropriate melting point temperature in the sealing mold, molding defects due to insufficient temperature can be suppressed. Further, since occurrence of abnormalities possibly causing an apparatus stop can be reduced, the operating rate can be improved.

Further, the start timing is preferably set to a time point at which the resin is set at a predetermined position of the sealing mold. Further, the end timing is preferably set to a time point at which the resin reaches a predetermined thermally cured state. According to this, the decrease in the surface temperature in the sealing mold can be effective suppressed.

Further, the predetermined temperature is preferably set to a temperature selected from a range of 1° C. to 20° C. According to this, optimal settings can be performed according to the material and amount of the resin, or the temperature decrease tendency or the like of the sealing mold. Thus, the molding quality can be better maintained.

Further, the switching setting temperature is preferably configured such that a setting temperature in the upper mold is set as a first switching setting temperature and a setting temperature in the lower mold is set as a second switching setting temperature, respectively. The first switching setting temperature is preferably set to a temperature higher than the second switching setting temperature. Further, the start timing is preferably configured such that a setting timing in the upper mold is set as a first start timing and a setting timing in the lower mold is set as a second start timing, respectively. The end timing is preferably configured such that a setting timing in the upper mold is set as a first end timing and a setting timing in the lower mold is set as a second end timing, respectively. A time from the first start timing to the first end timing is preferably set to a time longer than a time from the second start timing to the second end timing. According to these, it becomes possible to enhance the effect of suppressing temperature decrease in the upper mold more than in the lower mold. Thus, in the upper mold in which a large temperature decrease tends to occur in one cycle, suppression thereof can be achieved. Furthermore, individual adjustment becomes possible in each of the upper mold and the lower mold to obtain a surface temperature of the sealing mold more suitable for molding, and the molding quality can be further improved.

Further, a resin sealing apparatus according to the present invention is a resin sealing apparatus that seals a workpiece with a resin to process into a molded product using a sealing mold including an upper mold and a lower mold. As a requirement, the resin sealing apparatus includes a control part that controls a temperature of the sealing mold. The control part is configured to: take, as a normal setting temperature, a temperature of the sealing mold set as a temperature for appropriately thermally curing the resin during sealing, and take, as a switching setting temperature, a temperature of the sealing mold set as a temperature higher than the normal setting temperature by a predetermined temperature; and in a unit process in which the workpiece and the resin are carried into the sealing mold, sealed, and then carried out as the molded product, with respect to at least one of the upper mold and the lower mold, change a setting temperature to increase from the normal setting temperature to the switching setting temperature at a predetermined start timing to control the temperature of the sealing mold, and change the setting temperature from the switching setting temperature to the normal setting temperature at a predetermined end timing to control the temperature of the sealing mold.

### Effects of Invention

According to the present invention, it becomes possible to prevent gradual decrease in a surface temperature of a sealing mold and occurrence of molding defects by a simple configuration, even in the case of continuing a molding action of performing resin sealing by automatic operation at a constant period.

### BRIEF DESCRIPTION OF DRAWINGS

FIG. 1 is a plan view showing an example of a resin sealing apparatus according to an embodiment of the present invention.

FIG. 2 is a side view taken at a line II-II position in FIG. 1.

FIG. 3 is a front cross-sectional view showing an example of a sealing mold of the resin sealing apparatus in FIG. 1.

FIG. 4 is a graph showing temperature decrease tendencies of lower molds according to the embodiment of the present invention and a conventional embodiment.

FIG. 5 is a graph showing temperature decrease tendencies of upper molds according to the embodiment of the present invention and the conventional embodiment.

### DESCRIPTION OF EMBODIMENTS

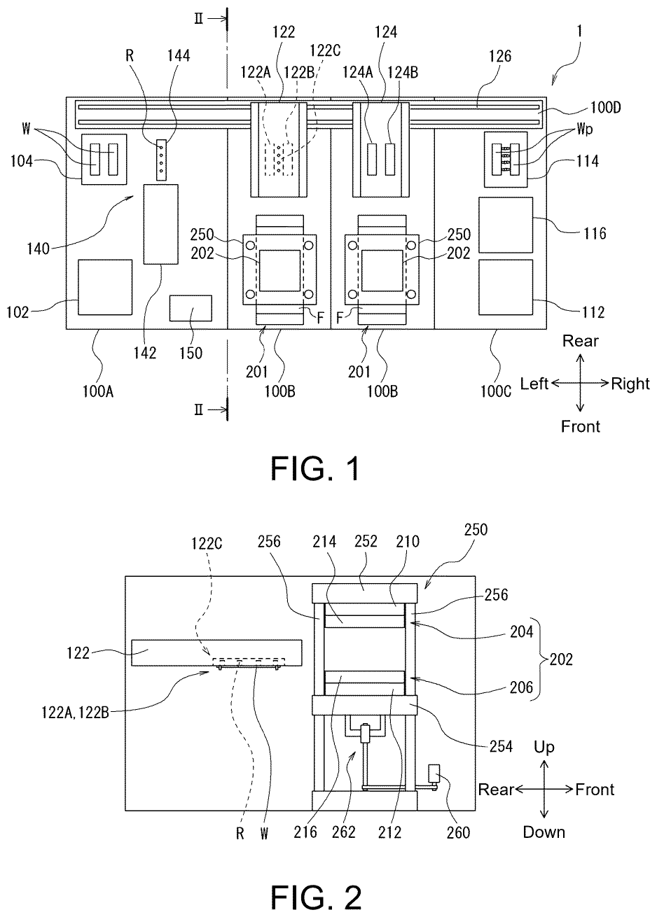

Hereinafter, embodiments of the present invention will be described in detail with reference to the drawings. FIG. 1 is a plan view (schematic view) showing an example of a sealing mold 202 according to an embodiment of the present invention and a resin sealing apparatus 1 including the sealing mold 202. Further, FIG. 2 is a side view taken at a line II-II position in FIG. 1 (some mechanisms are not shown). For convenience of illustration, front-rear, left-right, and up-down directions in the resin sealing apparatus 1 may be illustrated by arrows in the figures. Further, in all figures for illustrating each embodiment, members having the same functions will be labeled with the same reference signs, and repeated descriptions thereof may be omitted.

The resin sealing apparatus 1 according to the present embodiment is an apparatus that resin-seals a workpiece (molded product) W using a sealing mold 202 including an upper mold 204 and a lower mold 206. Hereinafter, as an example of the resin sealing apparatus 1, a resin sealing apparatus and method based on a transfer molding method will be described, in which the workpiece W is held by the lower mold 206, a cavity 208 (including a part of a mold surface 204a) provided at the upper mold 204 in a corresponding arrangement is covered with a release film (hereinafter, simply referred to as a “film”) F, and a clamping action between the upper mold 204 and the lower mold 206 is performed to seal the workpiece W with a resin R. However, the present embodiment is not limited thereto, and the cavity 208 may be provided at the upper mold 204 only or at both the lower mold 206 and the upper mold 204. Further, the film F is not necessarily required.

First, the workpiece W, which is the molding target, has a configuration in which one or more electronic components Wb are mounted on a substrate Wa in a predetermined arrangement. More specifically, examples of the substrate Wa include plate-shaped members such as a resin substrate, a ceramic substrate, a metal substrate, a carrier plate, a lead frame, a wafer, etc. formed into a rectangular shape, a circular shape etc. Further, examples of the electronic component Wb include a semiconductor chip, a MEMS chip, a passive element, a heat sink, a conductive member, a spacer, combinations thereof, etc. However, the present embodiment is not limited thereto.

Examples of the method of mounting the electronic component Wb onto the substrate Wa include mounting methods performed by wire bonding mounting, flip chip mounting, etc. Alternatively, in the case of a configuration in which the substrate (a carrier plate made of glass or metal) Wa is peeled off from a molded product Wp after resin sealing, there is also a method of attaching the electronic component Wb using an adhesive tape having thermal peeling properties or an ultraviolet-curable resin that cures by ultraviolet irradiation.

On the other hand, examples of the resin R include a thermosetting resin (e.g., an epoxy-based resin or the like containing a filler) in a tablet shape (as an example, a cylindrical shape). The resin R is not limited to the above state and may also be in a shape other than the cylindrical shape and may also be a resin other than an epoxy-based thermosetting resin.

Further, examples of the film F preferably include a film material excellent in heat resistance, peelability, flexibility, and stretchability, such as polytetrafluoroethylene (PTFE), polytetrafluoroethylene polymer (ETFE), PET, FEP, fluorine-impregnated glass cloth, polypropylene, polyvinylidene chloride, etc. In the present embodiment, a roll-shaped film is used as the film F. As another example, a strip-shaped film may also be used (not shown).

So far, the case of using a general workpiece W and resin R have been described. However, there may also be cases where molding is performed with the resin R alone into a predetermined shape without the workpiece W (in that case, referred to as a resin molding apparatus and method).

Next, an overview of the resin sealing apparatus 1 according to the present embodiment will be described. As shown in FIG. 1, the resin sealing apparatus 1 includes, as main configurations, a supply unit 100A that mainly performs supply of the workpiece W, which is the resin-sealing target, and the resin R, a press unit 100B that mainly resin-seals the workpiece W to process into a molded product Wp, and a storage unit 100C that mainly performs storage of the molded product Wp after resin sealing. A control part 150 that performs control on each mechanism in each unit is arranged at the supply unit 100A but may also be configured to be arranged at another unit.

Further, the resin sealing apparatus 1 includes a transport mechanism 100D that moves between each unit to perform transportation of the workpiece W, the resin R, and the molded product Wp. As an example, the transport mechanism 100D includes an in-loader 122 that carries the workpiece W and the resin R into the press unit 100B, an out-loader 124 that carries the molded product Wp out from the press unit 100B, and a guide rail 126 shared by the in-loader 122 and the out-loader 124. The transport mechanism 100D is not limited to the above configuration and may also be configured to incorporate a conventional pickup mechanism or the like as appropriate (not shown). Further, a configuration including a multi-joint robot (not shown) may be adopted instead of the configuration including the loaders.

Herein, the in-loader 122 functions to receive the workpiece W and the resin R in the supply unit 100A and transport to the press unit 100B. As a configuration example of the in-loader 122, workpiece holding parts 122A and 122B are provided to be arranged side by side in two columns along a left-right direction and each capable of holding one workpiece W. Further, a resin holding part 122C capable of holding a plurality (as an example, a case of four is illustrated, but the present embodiment is not limited thereto and the quantity may also be one) of resins R along a front-rear direction is provided at a position between the workpiece holding parts 122A and 122B in two columns. Conventional holding mechanisms (e.g., a configuration having a holding claw to perform clamping, a configuration having a suction hole communicating with a suction device to perform adsorption, etc.) are used as the workpiece holding parts 122A and 122B and the resin holding part 122C (not shown).

The in-loader 122 according to the present embodiment is configured to move in the left-right direction and the front-rear direction to carry the workpiece W and the resin R into the sealing mold 202 and place at a predetermined position on the lower mold 206. However, the present embodiment is not limited thereto and may also be configured to separately include a loader that moves in the left-right direction to perform transportation between units and a loader that moves in the front-rear direction to perform carry-in to the sealing mold 202 (not shown).

Further, the out-loader 124 functions to receive the molded product Wp (including unwanted resin portions such as a cull part, a runner part, etc.) in the press unit 100B to transport to the storage unit 100C. As a configuration example of the out-loader 124, molded product holding parts 124A and 124B are provided to be arranged side by side in two columns in the left-right direction and each capable of holding one molded product Wp. Conventional holding mechanisms (e.g., a configuration having a holding claw to perform clamping, a configuration having a suction hole communicating with a suction device to perform adsorption, etc.) are used as the molded product holding parts 124A and 124B (not shown).

The out-loader 124 according to the present embodiment is configured to move in the left-right direction and the front-rear direction to carry the molded product Wp out of the sealing mold 202 and place onto a molded product table 114. However, the present embodiment is not limited thereto and may also be configured to separately include a loader that moves in the front-rear direction to perform carry-out from the sealing mold 202 and a loader that moves in the left-right direction to perform transportation between units (not shown).

The overall configuration of the resin sealing apparatus 1 may be changed by changing the configurations of the units. For example, although the configuration shown in FIG. 1 is an example in which two press units 100B are installed, it is also possible to install only one press unit 100B or install three or more press units 100B. Further, it is also possible to additionally install other units (none is shown).

### (Supply Unit)

Next, the supply unit 100A included in the resin sealing apparatus 1 will be described.

As an example, the supply unit 100A includes a workpiece stocker 102 used for accommodating the workpiece W, and a workpiece table 104 on which the workpiece W is placed. The workpiece stocker 102 is a conventional stack magazine, a slit magazine, etc., and is capable of collectively accommodating a plurality of workpieces W. With this configuration, the workpiece W is taken out from the workpiece stocker 102 using a conventional pusher or the like (not shown) and placed onto the workpiece table 104 (as an example, two workpieces W in a group are placed and arranged side by side). Next, the workpieces W placed on the workpiece table 104 are held by the in-loader 122 and transported to the press unit 100B.

Further, the supply unit 100A (or another unit) includes a resin supply mechanism 140 that supplies the resin R at a lateral position of the workpiece table 104. As an example, the resin supply mechanism 140 includes a supply part 142 that has a hopper, a feeder, etc. to supply the resin R, and a handover part 144 that has a transfer mechanism such as an elevator or the like to hold a plurality of resins R supplied from the supply part 142 at predetermined positions. With this configuration, the plurality of resins R held at the handover part 144 are held by the in-loader 122 and transported to the press unit 100B.

### (Press Unit)

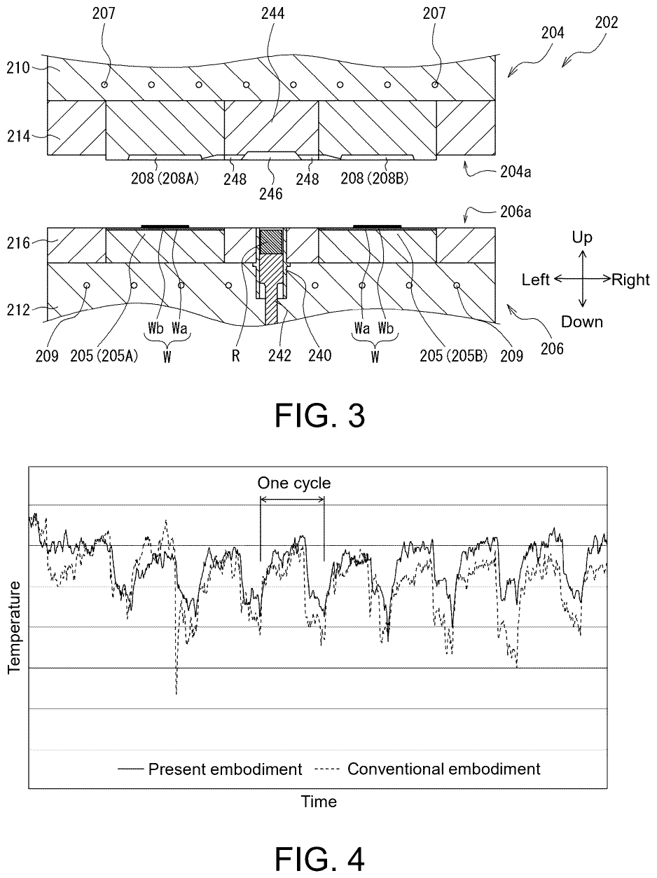

Next, the press unit 100B included in the resin sealing apparatus 1 will be described. Herein, FIG. 3 is a front cross-sectional view (schematic) of the sealing mold 202 of the resin sealing apparatus 1.

The press unit 100B includes a press apparatus 250 that clamps the workpiece W by driving opening and closing of the sealing mold 202 (to be described later) to resin-seal the workpiece W.

As shown in FIG. 2, the press apparatus 250 includes: a sealing mold 202 that has an upper mold 204 and a lower mold 206 and is arranged between a pair of platens 252 and 254; a plurality of connecting mechanisms 256 at which the pair of platens 252 and 254 are installed; a drive source (e.g., an electric motor) 260 that makes the platen 254 movable (rising and lowering); and a drive transmission mechanism (e.g., a ball screw or a toggle link mechanism) 262. In the present embodiment, the upper mold 204 is assembled to the fixed platen 252, and the lower mold 206 is assembled to the movable platen 254. However, the present embodiment is not limited to this configuration, and the upper mold 204 may also be assembled to a movable platen and the lower mold 206 may also be assembled to a fixed platen; alternatively, the upper mold 204 and the lower mold 206 may both be assembled to movable platens (not shown).

Further, the press unit 100B includes a film supply mechanism 201 that transports (supplies) the roll-shaped film F into the sealing mold 202. As described above, a strip-shaped film may also be used instead of the roll-shaped film (not shown).

Next, the lower mold 206 of the sealing mold 202 will be described in detail. As shown in FIG. 2 and FIG. 3, the lower mold 206 is configured by assembling a lower mold base 212, a lower mold chase block 216, etc., with its upper surface forming a mold surface 206a. As an example, the lower mold chase block 216 is fixed onto the lower mold base 212, and the lower mold base 212 is fixed onto the movable platen 254.

Herein, as an example, at the lower mold 206, a plurality (as an example, a case of four is illustrated, but the present embodiment is not limited thereto; alternatively, the quantity may also be one) of resin accommodating parts (in the present embodiment, pots 240 in a tubular shape in which the tablet-shaped resins R are accommodated) are provided along the front-rear direction as “predetermined positions” at which the resins R are set (accommodated). The pot 240 is formed as a through hole continuous with the lower mold chase block 216 and the lower mold base 212. Further, a plunger 242 that is pushed and driven by a conventional transfer drive mechanism (not shown) is arranged in the pot 240. With this configuration, the plunger 242 is pushed and driven to supply the resin R in the pot 240 into the cavity 208 (to be described later).

Further, in the present embodiment, a workpiece holding part 205 that holds one or more workpieces W is provided on the lower mold chase block 216. More specifically, as shown in FIG. 3, a predetermined quantity of sets (one or more sets) of a group of workpiece holding parts 205 (a first workpiece holding part 205A and a second workpiece holding part 205B) are arranged in the front-rear direction in an arrangement sandwiching a predetermined quantity (one or more) of pots 240 in the left-right direction. As an example, the workpiece holding part 205 is configured to include a suction path that communicates with a suction device (neither is shown) to adsorb and hold the workpiece W. A configuration including a holding claw that clamps the outer circumference of the workpiece W may also be adopted in addition to or instead of the configuration including the suction path, or a hole of the workpiece W may be simply inserted into a pilot pin and placed (not shown).

Further, in the present embodiment, a lower mold heating mechanism that heats the lower mold 206 to a setting temperature is provided. The lower mold heating mechanism includes a lower mold heater 209, a temperature sensor (not shown), etc. (or a tubular heater with a built-in temperature sensor), and the control part 150 performs control of heating such that the lower mold 206 becomes the setting temperature. As an example, the lower mold heater 209 may be a conventional electric wire heater, a sheath heater, or the like and is arranged at the lower mold base 212. Accordingly, heat is conducted to around the workpiece holding part 205 and the resin accommodating part (pot 240) via the lower mold chase block 216 and the like, and the workpiece W held at the workpiece holding part 205 and the resin R in the resin accommodating part (pot 240) can be heated to the setting temperature (e.g., 150° C. to 200° C.).

Next, the upper mold 204 of the sealing mold 202 will be described in detail. As shown in FIG. 2 and FIG. 3, the upper mold 204 is configured by assembling an upper mold base 210, an upper mold chase block 214, etc., with its lower surface forming a mold surface 204a. As an example, the upper mold chase block 214 is fixed below the upper mold base 210, and the upper mold base 210 is fixed below the fixed platen 252.

Herein, at the upper mold 204, a cull block 244 with a cull 246 and (a part of) a runner 248 provided through the lower surface is provided at a position directly above (herein, referring to a region of a predetermined size directly above) the pot 240 of the lower mold 206. Further, a cavity 208 is provided, in which a predetermined portion of the workpiece W (a portion at which the electronic component Wb is mounted) is accommodated. The cull 246 and the runner 248 in the upper mold 204 may be set at the “predetermined position (resin accommodating part)” at which the resin R is accommodated (in this case, passed or filled) to perform the control to be described later.

Regarding the cavity 208 according to the present embodiment, corresponding to positions at which a predetermined quantity of sets (one or more sets) of a group of workpiece holding parts 205 (the first workpiece holding part 205A and the second workpiece holding part 205B) in the lower mold 206 are arranged, a predetermined quantity of sets (one or more sets) of a group of cavities 208 (a first cavity 208A and a second cavity 208B) are arranged in the front-rear direction in an arrangement sandwiching the cull block 244 in the left-right direction in a plan view.

Further, in the present embodiment, an upper mold heating mechanism that heats the upper mold 204 to a setting temperature is provided. The upper mold heating mechanism includes an upper mold heater 207, a temperature sensor (not shown), etc. (or a tubular heater with a built-in temperature sensor), and the control part 150 performs control of heating such that the upper mold 204 becomes the setting temperature. As an example, the upper mold heater 207 is a conventional electric wire heater, a sheath heater, or the like and is arranged at the upper mold base 210. Accordingly, heat is conducted to around the cavity 208 and the resin flow path (the cull 246, the runner 248, etc.) via the upper mold chase block 214 and the like, and the resin R in the cavity 208 and the resin flow paths 246 and 248 can be heated to the setting temperature (e.g., 150° C. to 200° C.).

Herein, temperature control of the sealing mold 202 performed by the control part 150 will be described. As a term to be used below, a temperature of the sealing mold 202 set as a temperature for appropriately thermally curing the resin R at the time of sealing (depending on the material and amount of the resin R) is defined as a “normal setting temperature”. Further, a temperature of the sealing mold 202 set as a temperature higher than the “normal setting temperature” by a predetermined temperature (to be described later) is defined as a “switching setting temperature”.

As a specific example of the temperature control, in a unit process (one cycle) of carrying the workpiece W and the resin R into the sealing mold 202 and then carrying out as a molded product Wp after sealing, the control part 150 changes the setting temperature from the “normal setting temperature” to the “switching setting temperature” at a predetermined “start timing” to control the temperature of the sealing mold 202. Next, the setting temperature is changed from the “switching setting temperature” to the “normal setting temperature” at a predetermined “end timing” to control the temperature of the sealing mold 202.

As an example, the “start timing” described above is set to a time point (timing) at which the resin R is set (accommodated) at the “predetermined position” (in the present embodiment, the resin accommodating part (pot 240) of the lower mold 206) of the sealing mold 202. However, the present embodiment is not limited thereto, and instead of the above setting or together with the above setting (i.e., respectively and separately), the “start timing” may also be set to a time point (timing) at which the resin R is accommodated (passed or filled) in the resin accommodating part (the cull 246 and the runner 248) of the upper mold 204.

Further, as an example, the “end timing” described above is set to a time point (timing) at which the resin R reaches a predetermined thermally cured state (in the present embodiment, a state in which heating under pressure has been performed for a predetermined time). However, the present embodiment is not limited thereto.

Further, as an example, the “predetermined temperature” described above is set as a temperature selected from a range of 1° C. to 20° C. However, the present embodiment is not limited thereto. The temperature is set as appropriate according to the material and amount of the resin R, the size of the sealing mold 202, or the like.

According to the configuration described above, the aforementioned problem can be solved. That is, the following problem can be solved: in the case of continuing a molding action of performing resin sealing by automatic operation at a constant period, the surface temperature of the sealing mold 202 gradually decreases due to the influence of the temperature of the accommodated resin R, the melting point temperature required for resin sealing cannot be secured, and molding defects (insufficient resin curing, non-filling, etc.) occur.

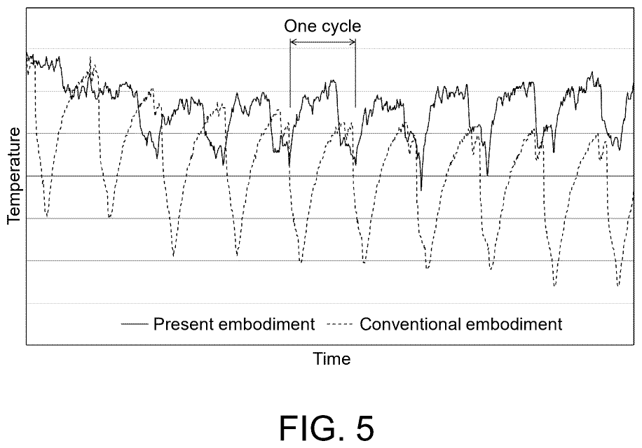

Specifically, as described above, the present embodiment includes a configuration of repeating, for each molding cycle, a process of changing the setting temperature from the “normal setting temperature” to the “switching setting temperature” at the “start timing” to control the temperature of the sealing mold 202, and changing the setting temperature from the “switching setting temperature” to the “normal setting temperature” at the predetermined “end timing” to control the temperature of the sealing mold 202. Accordingly, it becomes possible to prevent the surface temperature of the sealing mold 202 from gradually decreasing. Herein, FIG. 4 and FIG. 5 show results of an experiment conducted by the inventors of the present application for learning about the tendency of temperature decrease in the case of repeating the molding cycle (one cycle) at a constant period. FIG. 4 shows the results in the lower mold 206, and FIG. 5 shows the results in the upper mold 204. In both figures, the solid line represents the result according to the configuration of the present embodiment, and the broken line represents the result according to the configuration of a conventional embodiment.

As clearly shown in the above experimental results, according to the present embodiment, even if the molding action is continued by automatic operation at a constant period, it becomes possible to secure an appropriate melting point temperature corresponding to the resin R for performing resin sealing with the sealing mold 202, and molding defects due to insufficient temperature can be suppressed. Further, since occurrence of abnormalities possibly causing an apparatus stop can be reduced, the operating rate can be improved. Further, regarding the application of the present embodiment, the present embodiment becomes a more effective means especially for products (molded products) with a larger amount of the resin R used in one-time sealing.

Further, compared to the apparatus illustrated in Patent Document 1 described above, in the present embodiment, since it is not required to provide a temperature sensor at the upper mold chase block 214, simplification of the apparatus and cost reduction can be achieved.

The above embodiment is simply an example. In another embodiment, the “start timing” in the upper mold 204 may be set to a “first start timing”, and the “start timing” in the lower mold 206 may be set to a “second start timing”, respectively set to different time points (timings). Further, the “end timing” in the upper mold 204 may be set to a “first end timing”, and the “end timing” in the lower mold 206 may be set to a “second end timing”, respectively set to different time points (timings). As a specific example, it is conceivable to set a time from the “first start timing” to the “first end timing” to a time longer than a time from the “second start timing” to the “second end timing”.

In still another embodiment, the “switching setting temperature” may be set to different temperatures, respectively, with the setting temperature in the upper mold 204 set to a “first switching setting temperature” and the setting temperature in the lower mold 206 set to a “second switching setting temperature”. As a specific example, it is conceivable to set the “first switching setting temperature” to a temperature higher than the “second switching setting temperature”.

According to the research of the inventors of the present application, it has been found that in the case of continuing the molding action performing resin sealing by automatic operation at a constant period using, for example, a configuration in which a cull block 244 having a cull 246 and a runner 248 is provided at the upper mold 204, a temperature decrease in the molding cycle (one cycle) is more significant in the upper mold 204 than in the lower mold 206 (see FIG. 4 and FIG. 5). In response to this problem, in any of the above embodiments, since the effect of suppressing temperature decrease in the upper mold 204 can be enhanced more than in the lower mold 206, the problem can be solved. Upon consideration, it is deemed that, after mold clamping, since the resin (tablet) R hits the cull 246 of the upper mold 204, is melted, and is pressurized by the plunger 242, the temperature of the upper mold 204 decreases more than the lower mold 206 due to flow of the resin R. Furthermore, in each of the upper mold 204 and the lower mold 206, since it is possible to adjust to a surface temperature of the sealing mold 202 more suitable for molding, molding quality can be further improved. Further, in the case of a large resin (tablet) R, if it is desired to put the resin R into the pot 240 and pressurize it by the plunger 242 after melting sufficiently, the temperature of the lower mold 206 may be set to be higher than the upper mold 204, or the upper and lower molds may be set to a same temperature.

Next, another embodiment related to the configuration of the sealing mold 202 will be described. In the above embodiment, the cavity 208 is provided at the upper mold 204, but it may also be provided at the lower mold 206, or may be provided at both the upper mold 204 and the lower mold 206. In that case, since the pot 240 is provided at the lower mold 206, a configuration that causes the runner to communicate from the cull 246 of the upper mold 204 to the lower mold 206 may be adopted. Alternatively, in the case of a workpiece such as a lead frame, a configuration that allows the resin to pass in the up-down direction by a hole penetrating the workpiece in the up-down direction may be adopted (neither is shown).

### (Storage Unit)

Next, the storage unit 100C included in the resin sealing apparatus 1 will be described.

As an example, the storage unit 100C includes a molded product table 114 on which the molded product Wp is placed, a gate break part 116 that removes unwanted resin portions such as a cull part, a runner part, a gate part, etc. from the molded product Wp, and a molded product stocker 112 used for accommodating the molded product Wp from which the unwanted resin portions have been removed. The molded product stocker 112 is a conventional stack magazine, a slit magazine, etc. and is capable of collectively accommodating a plurality of molded products Wp. With this configuration, the molded products Wp (connected via the unwanted resin portions) transported from the press unit 100B using the out-loader 124 and the like are placed on the molded product table 114. Next, after the molded products Wp are transferred to the gate break part 116 using a conventional pickup mechanism or the like (not shown) and the unwanted resin portions are removed, the molded products Wp are accommodated in the molded product stocker 112 using a conventional pusher or the like (not shown).

### (Resin Sealing Action)

Next, an action of performing resin sealing using the resin sealing apparatus 1 according to the present embodiment (i.e., a resin sealing method according to the present embodiment) will be described. Herein, in a configuration provided as an example, a plurality of sets (or one set) of a group of cavities 208 are provided at one upper mold 204, a plurality of sets (or one set) of a group of workpiece holding parts 205 are provided at one corresponding lower mold 206, and workpieces W (e.g., workpieces in a strip shape or the like) are arranged at the workpiece holding parts 205 to collectively perform resin sealing and obtain a plurality of molded products Wp at the same time. However, the present embodiment is not limited to this configuration.

As a preparation process, a heating process (upper mold heating process) is performed to adjust and heat the upper mold 204 to a setting temperature (e.g., 150° C. to 200° C.) by the upper mold heater 207. Further, a heating process (lower mold heating process) is performed to adjust and heat the lower mold 206 to a setting temperature (e.g., 150° C. to 200° C.) by the lower mold heater 209. Furthermore, a process (film supply process) is performed to transport (feed out) a film F by the film supply mechanism 201 to supply the film F to a predetermined position (a position between the upper mold 204 and the lower mold 206) in the sealing mold 202.

Next, a process is performed to carry, by a conventional pusher or the like (not shown), the workpieces W one by one out from the workpiece stocker 102 and place onto the upper surface of the workpiece table 104 (a conventional pickup mechanism or the like may also be used together). Further, a process is performed to carry, by a conventional feeder, an elevator, etc. (not shown), the tablet-shaped resins R one by one out from the supply part 142 and hold a plurality (as an example, four) of resins R at predetermined positions of the handover part 144.

Next, the in-loader 122 is moved to directly above the workpiece table 104 (or may stand by in advance at the same position). At this position, a process is performed to raise the workpiece table 104 (or lower the in-loader 122) and hold the workpieces W by the workpiece holding parts 122A and 122B (in the present embodiment, the workpiece holding parts 122A and 122B each hold one workpiece W).

Next, the in-loader 122 is moved to directly above the handover part 144. At this position, a process is performed to raise the handover part 144 (or lower the in-loader 122) and hold the resin R by the resin holding part 122C (in the present embodiment, the resin holding part 122C holds four resins R).

Next, a process is performed to transport, by the in-loader 122, a plurality (in the present embodiment, two) of workpieces W and a plurality (in the present embodiment, four) of resins R into the sealing mold 202 of the press unit 100B in a one-time process, and place the workpieces W respectively at the workpiece holding parts 205 (in the present embodiment, the workpiece holding parts 205A and 205B) in the lower mold 206, and a process is performed to accommodate the resins R respectively in a plurality (in the present embodiment, four) of resin accommodating parts (pots 240) in the lower mold 206. During transportation, a process (preheating process) may be performed to preheat the workpieces W and the resins R by a heater (not shown) provided at the in-loader 122.

Next, a process (resin sealing process) is performed to perform mold closing of the sealing mold 202, and clamp the workpieces W by the upper mold 204 and the lower mold 206 and resin-seals the workpieces W to form molded products Wp.

Herein, in the present embodiment, in a unit process (one cycle) in which the workpieces W and the resins R are carried into the sealing mold 202 and sealed and then carried out as molded products Wp, the setting temperature is changed from the “normal setting temperature” to the “switching setting temperature” at the predetermined “start timing” to control the temperature of the sealing mold 202. Next, the setting temperature is changed from the “switching setting temperature” to the “normal setting temperature” at the predetermined “end timing” to control the temperature of the sealing mold 202. The settings of the “normal setting temperature” and the “switching setting temperature” as well as the “start timing” and the “end timing” are as described above, and repeated descriptions thereof will be omitted.

By heating and pressurizing the resins R with respect to the workpieces W as described above, the resins R are thermally cured to perform resin sealing (compression molding) and form molded products Wp.

Next, a process is performed to perform mold opening of the sealing mold 202, and take, by the out-loader 124, a plurality (in the present embodiment, two) of molded products Wp (in a state of including unwanted resin portions such as a cull part, a runner part, etc. and being connected via these unwanted resin portions) out of the sealing mold 202 in a one-time process.

In parallel with the above (or thereafter), a process is performed to feed out, by the film supply mechanism 201, the used film F by transporting the film F.

Next, a process is performed to place the molded products Wp (including the cull part, the runner part, etc.) onto the molded product table 114 by the out-loader 124 (a conventional pickup mechanism or the like may also be used together). Next, a process is performed to remove the unwanted resin portions such as the cull part, the runner part, etc. from the molded products Wp in the gate break part 116. Next, a process is performed to carry the molded products Wp (with the unwanted resin portions removed) one by one into the molded product stocker 112 by a conventional pusher or the like (not shown). Before these processes, a process of performing post-curing of the molded products Wp may also be performed.

The above are the main actions of resin sealing performed using the resin sealing apparatus 1. However, the above process sequence is an example, and a change in sequence or parallel performance is also possible as long as hindrance does not occur. For example, in the present embodiment, since two press units 100B are included, efficient formation of molded products becomes possible by performing the above actions in parallel.

As described above, according to the resin sealing apparatus and the resin sealing method of the present invention, it is possible to prevent the surface temperature of the sealing mold from gradually decreasing in the case of continuing the molding action by automatic operation at a constant period, without involving a complicated apparatus structure or a complicated implementation process. Thus, when performing resin sealing, since it becomes possible to secure an appropriate melting point temperature in the sealing mold, molding defects due to insufficient temperature can be suppressed. Further, since occurrence of abnormalities possibly causing an apparatus stop can be reduced, the operating rate can be improved.

The present invention is not limited to the above embodiments and may be subjected to various changes within the scope without departing from the present invention. Specifically, in the above embodiment, a configuration based on a transfer molding method has been described as an example, but the present invention is not limited thereto and may also be applied to a configuration based on a compression molding method. For example, in the case of a compression molding apparatus including a sealing mold with a cavity provided at the lower mold, a configuration may be adopted in which the resin is set (accommodated) in the cavity directly or via a film. Thus, the cavity may be taken as the “predetermined position” at which the resin is set to apply the above embodiment. On the other hand, in the case of a compression molding apparatus including a sealing mold with a cavity provided at the upper mold, as an example, a configuration may be adopted in which a workpiece with the resin placed thereon is held at the workpiece holding part of the lower mold, and next, by mold closing, the resin on the workpiece is set (accommodated) in the cavity directly or via a film. Thus, the workpiece holding part or the cavity may be taken as the “predetermined position” at which the resin is set to apply the above embodiment. Alternatively, as another example, a configuration may be adopted in which the resin placed on the resin loader is set (accommodated) in the cavity by pressing and adhering to the cavity bottom directly or via a film. Thus, the cavity may be taken as the “predetermined position” at which the resin is set to apply above embodiment.

1. A resin sealing method that seals a workpiece with a resin to process into a molded product using a sealing mold comprising an upper mold and a lower mold, wherein
a temperature of the sealing mold set as a temperature for appropriately thermally curing the resin during sealing is taken as a normal setting temperature, and a temperature of the sealing mold set as a temperature higher than the normal setting temperature by a predetermined temperature is taken as a switching setting temperature, and
in a unit process in which the workpiece and the resin are carried into the sealing mold, sealed, and then carried out as the molded product, with respect to at least one of the upper mold and the lower mold, a setting temperature is changed to increase from the normal setting temperature to the switching setting temperature at a predetermined start timing to control the temperature of the sealing mold, and the setting temperature is changed from the switching setting temperature to the normal setting temperature at a predetermined end timing to control the temperature of the sealing mold.

2. The resin sealing method according to claim 1, wherein
the start timing is set to a time point at which the resin is set at a predetermined position of the sealing mold.

3. The resin sealing method according to claim 1, wherein
the end timing is set to a time point at which the resin reaches a predetermined thermally cured state.

4. The resin sealing method according to claim 1, wherein
the predetermined temperature is set to a temperature selected from a range of 1° C. to 20° C.

5. The resin sealing method according to claim 1, wherein
the switching setting temperature is configured such that a setting temperature in the upper mold is set as a first switching setting temperature and a setting temperature in the lower mold is set as a second switching setting temperature, respectively, and
the first switching setting temperature is set to a temperature higher than the second switching setting temperature.

6. The resin sealing method according to claim 1, wherein
the start timing is configured such that a setting timing in the upper mold is set as a first start timing and a setting timing in the lower mold is set as a second start timing, respectively,
the end timing is configured such that a setting timing in the upper mold is set as a first end timing and a setting timing in the lower mold is set as a second end timing, respectively, and
a time from the first start timing to the first end timing is set to a time longer than a time from the second start timing to the second end timing.

7. A resin molding method that heats and pressurizes a resin to process into a molded product using a sealing mold comprising an upper mold and a lower mold, wherein
a temperature of the sealing mold set as a temperature for appropriately thermally curing the resin during sealing is taken as a normal setting temperature, and a temperature of the sealing mold set as a temperature higher than the normal setting temperature by a predetermined temperature is taken as a switching setting temperature, and
in a unit process in which the resin is carried into the sealing mold, processed, and then carried out as the molded product, with respect to at least one of the upper mold and the lower mold, a setting temperature is changed to increase from the normal setting temperature to the switching setting temperature at a predetermined start timing to control the temperature of the sealing mold, and the setting temperature is changed from the switching setting temperature to the normal setting temperature at a predetermined end timing to control the temperature of the sealing mold.

8. A resin sealing apparatus that seals a workpiece with a resin to process into a molded product using a sealing mold comprising an upper mold and a lower mold, the resin sealing apparatus comprising:
a control part that controls a temperature of the sealing mold, wherein
the control part is configured to:
take, as a normal setting temperature, a temperature of the sealing mold set as a temperature for appropriately thermally curing the resin during sealing, and take, as a switching setting temperature, a temperature of the sealing mold set as a temperature higher than the normal setting temperature by a predetermined temperature, and
in a unit process in which the workpiece and the resin are carried into the sealing mold, sealed, and then carried out as the molded product, with respect to at least one of the upper mold and the lower mold, change a setting temperature to increase from the normal setting temperature to the switching setting temperature at a predetermined start timing to control the temperature of the sealing mold, and change the setting temperature from the switching setting temperature to the normal setting temperature at a predetermined end timing to control the temperature of the sealing mold.
